(19) United States
(12) Patent Application Publication
(10) Pub. No.: US 2024/0077843 A1
(43) Pub. Date: Mar. 7, 2024

(54) INDUSTRIAL PROCESS CONTROLLER AND METHOD FOR AUTOMATICALLY DETECTING EXPANSION MODULES COUPLED TO SAID PROCESS CONTROLLER

(71) Applicant: NOVUS PRODUTOS ELETRÔNICOS LTDA., Canoas (BR)

(72) Inventors: Aderbal FERNANDES LIMA, Porto Alegre (BR); Miguel FACHIN JÚNIOR, Porto Alegre (BR); Marcos RE- BELLO DILLENBURG, Porto Alegre (BR)

(21) Appl. No.: 18/272,341

(22) PCT Filed: Mar. 12, 2021
(86) PCT No.: PCT/BR2021/050106

§ 371 Date: Jul. 13, 2023

(30) Foreign Application Priority Data
Feb. 26, 2021 (BR) BR102021003753-9

(51) Int. Cl. G05B 19/05

(52) U.S. Cl. CPC G05B 19/054; G05B 19/052

(57) ABSTRACT

A process controller is described, along with a method for automatically detecting expansion modules that can be coupled to said modular process controller, which is provided with a frame (20) for receiving the expansion modules (30) to enable the functionalities of the controller to be expanded by the user, depending on the requirements of the application, in which the expansion modules are detected automatically by the main module (10) of the process controller using a dedicated communication interface.

### CROSS-REFERENCE TO RELATED APPLICATION(S)

The present application is a U.S. national phase of International Patent Application No. PCT/BR2021/050106, entitled INDUSTRIAL PROCESS CONTROLLER AND METHOD FOR AUTOMATICALLY DETECTING EXPANSION MODULES COUPLED TO SAID PROCESS CONTROLLER, filed on Mar. 12, 2021, which claims priority to Brazilian Patent Application No. 102021003753-9, filed on Feb. 26, 2021, all of which are incorporated by reference herein.

### TECHNICAL FIELD

The present invention patent describes a method of automatic detection of expansion modules attachable to a modular type process controller provided with a rack to receive said modules that will allow the expansion of the controller's functionalities by the user, according to the needs of the application, with the expansion modules detected automatically by the main module of the process controller through a dedicated communication interface.

### BACKGROUND OF INVENTION

Controllers are widely used in logical process control, managing input variables and defining, through a process implemented in a computer program, control and operation actions.

Process controllers can be user programmable (known as Programmable Logic Controllers (PLC)) or they can be fixed programmable.

Transducers are connected to the controller inputs, which electrically inform the process variables to a processing unit that, in turn, analyzes the input information, executes its control logic and commands the activation and deactivation of its outputs, that are connected to actuator elements (devices that interact with the process) in order to control it.

PID process controllers for panel mounting are controllers specialized in regulating one or more magnitudes of processes, such as temperature, flow, pressure, level, positioning, among others.

pressure, level, positioning, among others.

PID process controllers for panel mounting are offered in enclosures with standardized dimensions, according to the IEC 61554 standard, with the most popular panel dimensions being: 48×48 mm, 48×96 mm e 96×96 mm. Basically, these process controllers comprise a main module containing the processing unit, display, keys, power supply, a set of inputs and outputs and electromechanical connections for signals from sensors, transducers and external actuators.

Process PID controllers are typically continuously reading an analog (sensor) input, comparing it to a reference value for the process being controlled. (setpoint) and acting on an output according to the perceived difference between what is desired for the process and what is actually happening (PID loop). Furthermore, the variable that is being read and controlled (temperature, for example) can be used to trigger alarm situations or can be read by external agents through communication interfaces. In a typical PID process controller, all these elements are part of the original product.

Document CN107329449 describes a method for creating a plug and play (PnP) module for a programmable logic controller (PLC) based on an AB system, which comprises the following steps: first, operate the PLC to be loaded using the RSlogix5000 software; then create a program, editing it through the editing module; and, finally, selecting a memory card to record the correlation matrices of inputs and outputs generated by the program, which is encrypted for security.

Document KR20180036089 describes a dynamic system of plug and play logistics automation equipment (PnP) that allows the free use of distribution equipment, regardless of the equipment manufacturer, through a dynamic PnP after registration of the distribution equipment, integrating a warehouse control system (WCS) that manages automation equipment in a distribution warehouse with an equipment control system (ECS) that monitors the control of each single piece of equipment and an operational status.

Document KR20190116060 describes a plug and play intelligent control system based on a general purpose IoT node and a method to recognize the type of a sensor in your system. The system comprises a IoT module and a control server. The IoT module detects an external environment using a plurality of sensors and an actuator before downloading information or sending a command to the outside. The control server receives the detected information from the LoT module via wired/wireless communication and transmits information to control the actuator to the corresponding LoT module. The IoT module includes a plurality of slots to which sensors are coupled. The number and alignment order of sensor wires in slots are defined identically in all slots. In the case of a specific sensor with the number or order of wire alignment defined differently from the standard, an auxiliary board is used to match the connections. Furthermore, the specific sensor is connected to the slot through a recognition method through resistance voltage distribution or through a specific frequency response characteristic by an LC resonance circuit.

Document US2012292096 describes a plug and play modular connectivity platform, system and method. The disclosed plug and play modular connectivity platform provides a convergence/distribution/conversion point for various services and transmission media. In exemplary embodiments, the platform includes a baseplate configured to be installed on a wall over a junction box that can support one or more distribution or data conversion modules. An interchangeable plate attaches to the base plate and provides interfaces for one or more data distribution or conversion modules. A cover attaches to the baseplate and forms a cabinet that encompasses all distribution or data conversion modules supported by the baseplate.

Document WO2005025192 describes a modular communication, command and control system with plug and play connectivity, using configurable independent base stations and portable devices that, preferably, have similar components and functionalities to be interoperable. The system uses an open system interconnect architecture, preferably with fully integrated layers, allowing interoperability with adaptive applications and inter/intra-linking with external devices and/or appliances. Optionally, the system can be used to perform extended information handling/processing, networking, personal assistance, industrial, commercial, medical, military and/or security functions.

Document U.S. Pat. No. 4,903,192 describes a system comprising a PID controller controlling a process that represents an object to be controlled and an automatic adjuster producing a PID control output (manipulated variable) in order to obtain the necessary performance indices and calculate, based on performance indexes, optimal control parameters to automatically adjust the control parameters to generate a control output that produces the best response for the system.

Document JPH08137557 describes a temperature controller with an ideal arrangement of the electronic circuits in order to reduce the size and cost of the controller and also to obtain the simple attachment of a printed board to improve the assembly process.

Document U.S. Pat. No. 4,250,563 describes a programmable controller with a processor module, one or more I/O modules, and a chassis into which the modules are inserted, which can be expanded by replacing the main slot processor module with a chassis adapter module that connects to a separate processor unit. The rack unit converts from a controller rack to one of several I/O interface racks that can be connected to the separate processor unit. The removable processor module integrates the processing functions of the separate processor unit and the parity checking, decoding, and buffering functions of the rack adapter module.

The rack cabinet provides a universal connector between the I/O modules and the selected module for insertion into the main slot.

Document US2019369649 describes an interfaced controller having a plug and play recognition approach with an automatic user interface completion mechanism. A check can be made for sensors connected to the controller. The type of control of the sensors can be determined. The menu structure can be repopulated based on the control type. The user interface can then be updated. This approach can be repeated as needed.

Document US2015347161 describes input/output devices with reconfigurable functionality in the components of the I/O devices without the need to disconnect the components from each other.

The prior art describes controllers with plug and play mechanisms that use sophisticated and expensive architectures, often requiring advanced technical knowledge, such as programming. In the specific case of PID controllers for panel mounting, the state of the art describes controllers without the ability to easily reconfigure or expand their hardware characteristics in the field, conditions that become economically unfeasible for smaller applications, but no less demanding.

Aiming to provide a viable technical solution for application in controllers, the object of this invention patent is an industrial process controller and a method of automatic detection of expansion modules coupled to said controller that allows the expansion of the controller's functionalities by coupling expansion to a plug and play rack, these modules being automatically detected and enabled by the controller's main module, which makes its functions available for configuration and immediate use by the controller user.

### SUMMARY

The invention describes a modular process controller in a housing suitable for panel mounting in standard formats 48×48 mm, 48×96 mm and 96×96 mm, with plug and play expansion modules.

The invention describes a modular process controller that allows the installation and removal of expansion modules without the need for tools, by the user himself.

The invention describes a modular process controller that receives a plug-in rack with a fastening mechanism and plug and play capability to support expansion modules.

The invention describes a modular process controller provided with a communication bus for interfacing with the expansion modules via a bus and communication protocol for automatic recognition, identification and data exchange with the modules.

The invention describes a modular process controller that adapts to different types of modules, without having to know them in advance.

### BRIEF DESCRIPTION OF THE DRAWINGS

FIG. 1 shows the perspective view showing the controller with the rack and three expansion modules of different formats connected.

FIG. 2 shows an exploded view showing the controller, the rack and the expansion modules.

FIG. 3A shows the bottom view of the rack and FIG. 3B shows details of the rack's electrical connections

FIG. 4 shows a perspective view of the expansion module.

FIG. 5 shows the flowchart of the method of automatic detection of expansion modules coupled to the main module of a process controller.

FIG. 6 shows the flowchart of the discovery step of the expansion modules attached to the rack.

FIG. 7 shows the automatic configuration flowchart of the modular process controller.

FIG. 8A shows the operation flowchart of the I/O expansion module and FIG. 8B shows the operation flowchart of the communication expansion module.

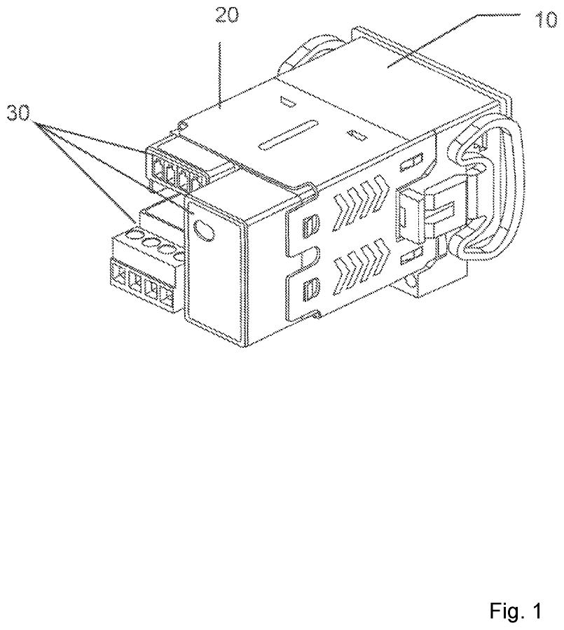

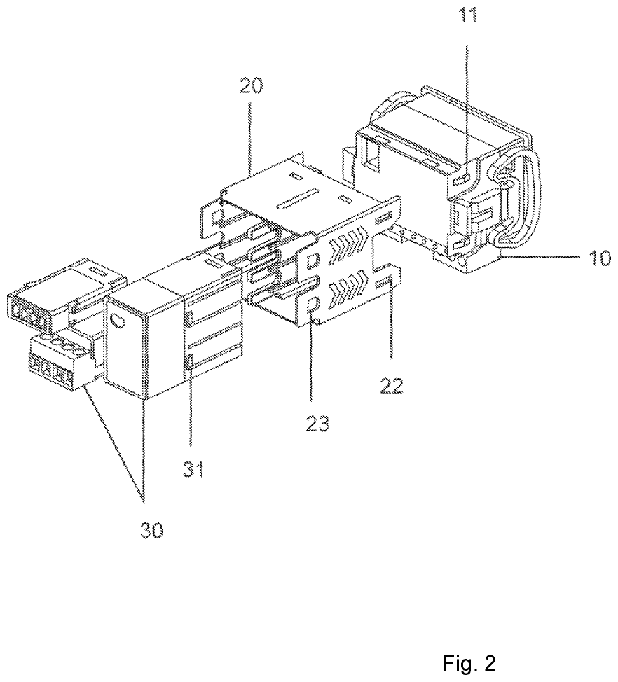

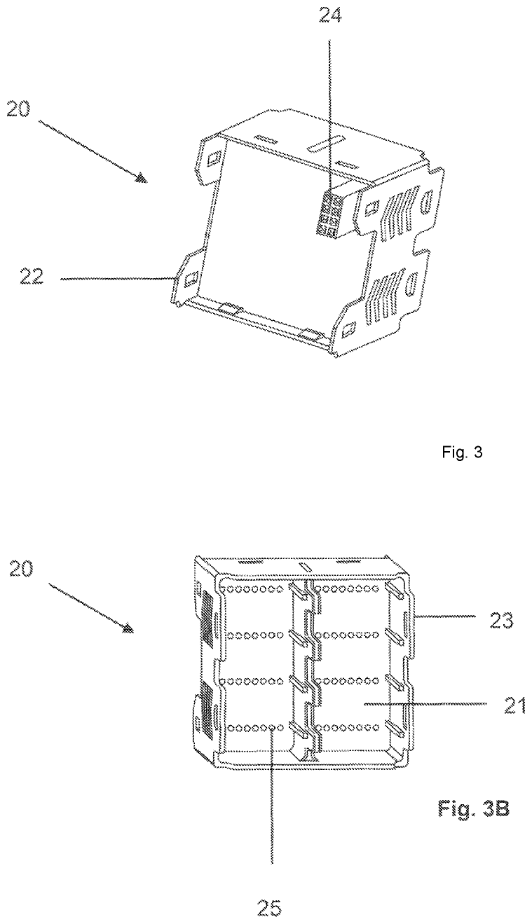

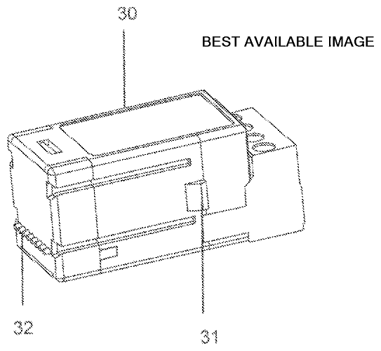

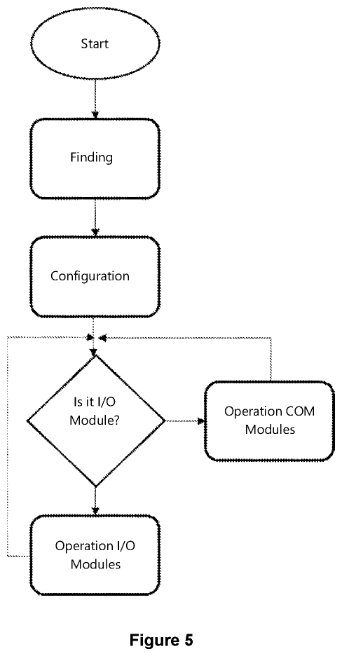

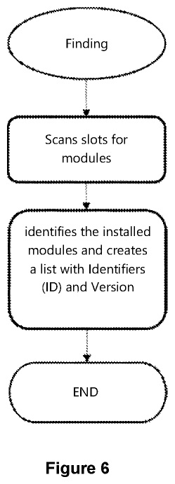

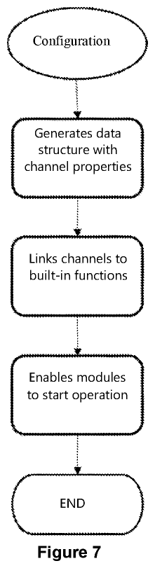

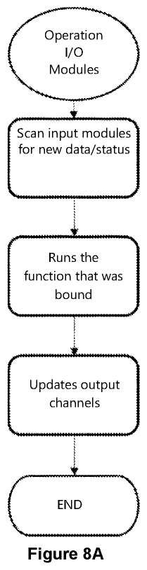

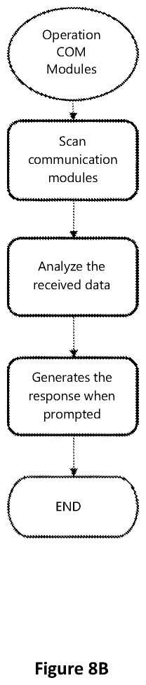

### DETAILED DESCRIPTION OF THE INVENTION

For the purposes of the present invention, the following terms are conceptualized:

“expansion module” (30) comprises an electronic unit provided with analog or digital inputs or outputs and/or communication interfaces, which may be I/O modules (input/output) or communication modules;

“main module” (10) comprises an electronics unit provided with a processing unit with a computer program for executing instructions for identifying, configuring and operating the expansion modules (30) associated with it, the main module (10) having a display, keys, power supply and a set of inputs and outputs.

The controller of industrial processes, object of the present patent, comprises a main module (10) on whose base a frame (20) is arranged that allows the coupling of at least one expansion module (30) to be automatically detected and enabled by the main module (10), ensuring field expansion of the functions of said process controller.

The rack (20) can be an integral structure of the main module (10), constituting a single body, or said rack (20) can be coupled to the main module (10).

The mechanical coupling of the frame (20) to the base of the main module (10) is effected by fitting at least one flap provided with a through hole (22) projecting from the frame (20) in at least one recess with a shoulder central (11) arranged at the base of the main module (10).

The rack (20) has a connector (24) that provides the electrical connection to the main module (10), interconnecting the rack communication bus (20) to the power supply and the main module communication interface (10).

The rack (20) has a communication bus equipped with sets of electrical connections (25) that are repeated in each position reserved for the connection of an expansion module (30), each set of electrical connections (25) having a communication address single (E) on the communication bus, configuring a compartment or slot (21). The communication bus provides electrical power to the expansion modules (30) and connects each expansion module (30) to a communication interface address of the main module (10).

The expansion module (30) is mechanically coupled to the frame (20) by fitting a flap with a through hole (23) that protrudes from the frame (20) on the opposite side to the flap (22) in a ledge (31) arranged in coincident position on the surface of the expansion module (30).

The mechanical coupling of the expansion modules (30) facilitates the integration and removal of the main module (10), eliminating the need to open the main module cabinet (10), an operation carried out in state-of-the-art controllers that have expansion modules internal to the main module.

The expansion module (30) has spring-loaded connectors (32) that connect to the electrical connections (25) of the rack (20) for electrical coupling.

Each expansion module (30) presents a configuration and operation data structure, identified by the main module processor (10) when coupling occurs, allowing the creation of dynamic configuration screens of the expansion modules (30) by the user and for operation of the expansion modules (30) according to the functions linked to said expansion module (30) during configuration.

Once the expansion module (30) is attached to the rack (20) and the electrical connections are established, the unique identifier (ID) of the expansion module (30) is read by the main module processing unit (10) in the discovery step, detecting the presence of the coupling of a certain expansion module (30) to the main module (10).

In the finding stage, the main module processing unit (10) sends signals to all slots (21) of the rack (20) through the electrical connections (25) of the communication bus. The installed expansion modules (30) are identified, listed and enabled by the main module processing unit (10) using the unique identifier (ID) of each expansion module (30) and the address (E) of the slot (21) occupied by the expansion module (30).

In a step following the discovery step, the expansion modules (30) are configured. In this step, the expansion modules (30) detected in the previous step send to the main module processing unit (10) their configuration and operation data structures through the electrical connections (25) of the communication bus, so that said data structures are used by the main module processor (10) for creating dynamic screens associated with each expansion module (30) installed that link the functions of the main module (10) to the expansion modules (30) installed in the rack (20).

In the configuration stage, the user links the process controller functions to each expansion module (30) coupled to the main module (10) through navigation on the display. As an example of functions of the main module (10) manually assigned to the expansion modules (30) through navigation on the display of the main module (10) we have: sensor input for the PID control function, signal output for the actuator of the PID control function, signaling output for high alarm function, input to enable ramp and soak program function, communication interface using Modbus protocol, current measurement input for burnt actuator detection function, output for sensor signal retransmission.

The main module processing unit (10) determines the controller functions that can be linked to each expansion module (30) installed based on the data structures obtained from these modules (30) in the configuration step.

In this way, expansion modules (30) with input capability are linked to input functions of the modular process controller; Expansion modules (30) with output capability are linked to output functions and expansion modules (30) with communication capability are linked to communication functions.

Optionally, linking the process controller functions to each expansion module (30) coupled to the main module (10) is done using external computer programs that communicate with the modular process controller through the communication interfaces.

In the operating stage, the main module processing unit (10) performs control functions similar to the state of the art in PID process controllers. The input, output and communication electrical signals are directed to the respective expansion modules (30) according to the binding made in the configuration step. The main module processing unit (10) only performs the control functions to which there are linked expansion modules (30).

Before the main module (10) executes a function that depends on an input signal in an expansion module (30) of the I/O type, this signal is read from the expansion module (30) through the communication bus. After the main module (10) executes a control function, which results in a new value for the output signal in an expansion module (30) of the I/O type, this value is sent to the expansion module (30) through of the communication bus.

The main module (10) reads data from the expansion modules (30) of the COM type at regular intervals, through the communication bus. The received data are processed by the communication functions of the main module (10). If the communication functions of the main module (10) result in data being transmitted by the installed COM-type expansion modules, said data is sent to said expansion modules (30) through the communication bus.

1. INDUSTRIAL PROCESSES CONTROLLER characterized for comprise:
a) a main module (10) provided with a recess with a central projection (11) arranged in the base;
b) a frame (20) equipped with a flap provided with a through hole (22) that fits into the ledge (11) arranged at the base of the main module (10) and a flap with a through hole (23) that projects from the face opposite the flap (22) that fits into the shoulder (31) arranged in a coincident position on the surface of the expansion module (30), the rack (20) having a communication bus provided with sets of electrical connections (25) with a unique communication address (E), configuring a compartment or slot (21) and a connector (24) that interconnects the communication bus of the rack (20) to the power supply and to the communication interface of the main module (10);
c) expansion module (30) positioned in a compartment (21) of the rack (20) through the coupling of connectors with spring (32) in the electrical connections (25) of the rack (20), each expansion module (30) having a structure of configuration and operation data and a unique identifier (ID) read by the main module processing unit (10), detecting the presence of the coupling of a certain expansion module to the main module (10).

2. INDUSTRIAL PROCESSES CONTROLLER, according to claim 1, characterized in that the rack (20) is an integral structure of the main module (10), constituting a single body.

3. AUTOMATIC DETECTION METHOD OF EXPANSION MODULES COUPLED IN THE PROCESS CONTROLLER claimed in 1, characterized by comprising the steps:
a) main module processing unit (10) sends signals to all slots (21) of the rack (20) through the electrical connections (25) of the communication bus;
b) installed expansion modules (30) are identified, listed and enabled by the main module processing unit (10) using the unique identifier (ID) of each expansion module (30) and the address (E) of the slot (21) occupied by the expansion module (30);
c) expansion modules (30) detected in step (b) send to the main module processing unit (10) their configuration and operation data structures through the electrical connections (25) of the communication bus;
d) data structures of the expansion modules (30) are used by the processor of the main module (10) for the creation of dynamic screens associated with each installed expansion module (30) that link the functions of the main module (10) to the expansion modules (30) installed in the rack (20);
e) user links the process controller functions to each expansion module (30) coupled to the main module (10) through navigation on the display;
f) main module processing unit (10) determines the controller functions that can be linked to each expansion module (30) installed based on the data structures obtained from these modules (30) in the configuration step;
g) electrical input, output and communication signals from the process controller are directed to the respective expansion modules (30) according to the binding made in the configuration stage.

4. METHOD, according to claim 3, characterized by linking the process controller functions to each expansion module (30) coupled to the main module (10) through external computer programs that communicate with the modular process controller through the communication interfaces.
